(19) United States
(12) Patent Application Publication
(10) Pub. No.: US 2024/0178337 A1
(43) Pub. Date: May 30, 2024

(54) Optical Sensing Apparatus

(71) Applicant: ARTILUX, INC., MENLO PARK, CA (US)

(72) Inventors: Yen-Ju Lin, HSINCHU COUNTY (TW); Yun-Chung Na, SAN JOSE, CA (US)

(21) Appl. No.: 18/367,773

(22) Filed: Sep. 13, 2023

Related U.S. Application Data
(60) Provisional application No. 63/385,210, filed on Nov. 29, 2022.

(51) Int. Cl. H01L 31/101; H01L 31/0336; H01L 31/107

(52) U.S. Cl. CPC H01L 31/1013; H01L 31/0336; H01L 31/1075

(57) ABSTRACT

An optical sensing apparatus includes a first photo-detecting layer having a first absorption region configured to absorb light in at least a visible spectrum; a second photo-detecting layer formed over the first photo-detecting layer, the second photo-detecting layer having a second absorption region configured to absorb light in at least a mid-infrared spectrum; a first buffer layer formed over the second photo-detecting layer; and a second buffer layer formed over the first photo-detecting layer and under the second photo-detecting layer.

### RELATED APPLICATION

The present application claims priority under 35 USC § 119(e) to U.S. Provisional Patent Application Ser. No. 63/385,210, having a filing date of Nov. 29, 2022, the entire content of which is incorporated herein by reference.

### TECHNICAL FIELD

The present disclosure relates generally to optical sensors.

### BACKGROUND

Sensors are being used in many applications, such as smartphones, robotics, autonomous vehicles, proximity sensing, biometric sensing, image sensors, high-speed optical receiver, data communications, direct/indirect time-of-flight (TOF) ranging or imaging sensors, medical devices, etc. for object recognition, image enhancement, material recognition, and other relevant applications.

### SUMMARY

Aspects and advantages of embodiments of the present disclosure will be set forth in part in the following description, or may be learned from the description, or may be learned through practice of the embodiments.

One example aspect of the present disclosure is directed to an optical sensing apparatus includes a first photo-detecting layer having a first absorption region configured to absorb light in at least a visible spectrum: a second photo-detecting layer formed over the first photo-detecting layer, the second photo-detecting layer having a second absorption region configured to absorb light in at least a mid-infrared spectrum; a first buffer layer formed over the second photo-detecting layer: and a second buffer layer formed over the first photo-detecting layer and under the second photo-detecting layer. In some implementations, at least one of the first buffer layer or the second buffer layer includes a monolayer graphene or a multi-layer graphene.

In some implementations, the optical sensing apparatus includes a first contact formed over the first photo-detecting layer and a second contact formed over the first buffer layer. In some implementations, the first photo-detecting layer includes a charge region configured to amplify charge-carriers generated in the second absorption region. In some implementations, the first photo-detecting layer includes a well region electrically coupled to the second contact, where the well region is configured to guide the amplified charge-carriers to the second contact.

In some implementations, the optical sensing apparatus includes a third photo-detecting layer formed between the first photo-detecting layer and the second photo-detecting layer, the third photo-detecting layer including a third absorption region configured to absorb light in at least a short-wavelength mid-infrared spectrum. In some implementations, the optical sensing apparatus includes a third contact formed over the third photo-detecting layer.

In some implementations, the optical sensing apparatus includes a passivation layer formed between the third photo-detecting layer and the second buffer layer. In some implementations, the first photo-detecting layer includes silicon, the second photo-detecting layer includes a two-dimensional material (e.g., black phosphorus), the third photo-detecting layer includes germanium, and the passivation layer includes epitaxy silicon or amorphous silicon.

In some implementations, the first photo-detecting layer includes p-doping, the second photo-detecting layer includes n-doping, p-doping, or is intrinsic (or includes an intrinsic region), the third photo-detecting layer includes p-doping, and the passivation layer includes p-doping. In some other implementations, the first photo-detecting layer includes n-doping, the second photo-detecting layer includes p-doping, the third photo-detecting layer includes p-doping, and the passivation layer includes p-doping.

Another example aspect of the present disclosure is directed to an optical sensing apparatus that includes a silicon layer including a first absorption region configured to absorb light in at least a visible spectrum: a germanium layer formed over the silicon layer, the germanium layer including a second absorption region configured to absorb light in at least a short-wave infrared (SWIR) spectrum: a black phosphorus layer formed over the germanium layer, where the black phosphorus layer is configured to absorb light in at least a mid-infrared spectrum: a first buffer layer formed over the black phosphorus layer: and a second buffer layer formed over the silicon layer and under the black phosphorus layer.

Another example aspect of the present disclosure is directed to an optical sensing apparatus that includes a silicon layer including a first absorption region configured to absorb light in at least a visible spectrum: a germanium layer formed over the silicon layer, the germanium layer including a second absorption region configured to absorb light in at least a SWIR spectrum: a two-dimensional-material layer formed over the germanium layer, where the two-dimensional-material layer is configured to absorb light in at least a mid-infrared spectrum: a first buffer layer formed over the black phosphorus layer: and a second buffer layer formed over the silicon layer and under the black phosphorus layer. In some implementations, the two-dimensional material layer includes graphene, MXene, topological insulators, or transition metal dichalcogenides.

The techniques implemented herein can provide sensors, more particularly, optical sensors, that detect light in the visible (e.g., wavelength range from 380 nm to 780 nm, or any similar wavelength range as defined by a particular application), the near-infrared (NIR, e.g., wavelength range from 780 nm to 1000 nm, or any similar wavelength range as defined by a particular application), the short-wave infrared (SWIR, e.g., wavelength range from 1000 nm to 3000 nm, or any similar wavelength range as defined by a particular application), and/or the mid-wave infrared (MIR, e.g., wavelength range from 3000 nm to 5000 nm, or any similar wavelength range as defined by a particular application). The techniques implemented herein can provide photodetectors that can detect light spanning over a wide spectrum (e.g., from visible to MIR spectrum).

These and other features, aspects and advantages of various embodiments will become better understood with reference to the following description and appended claims. The accompanying drawings, which are incorporated in and constitute a part of this specification, illustrate embodiments of the present disclosure, and together with the description, serve to explain the related principles.

### BRIEF DESCRIPTION OF THE DRAWINGS

The foregoing aspects and many of the advantages of this application will become more readily appreciated as the same becomes better understood by reference to the following detailed description, when taken in conjunction with the accompanying drawings:

FIGS. 1A-1G illustrate a cross-sectional view of example photodetectors.

FIG. 2 shows a block diagram of an example sensing system.

FIGS. 3A-3B illustrate a cross-sectional view of example photodetectors.

Like reference numbers and designations in the various drawings indicate like elements.

### DETAILED DESCRIPTION

As used herein, the terms such as “first”, “second”, “third”, “fourth” and “fifth” describe various elements, components, regions, layers and/or sections, these elements, components, regions, layers and/or sections should not be limited by these terms. These terms may be only used to distinguish one element, component, region, layer or section from another. The terms such as “first”, “second”, “third”, “fourth” and “fifth” when used herein do not imply a sequence or order unless clearly indicated by the context. The terms “photo-detecting”, “photo-sensing”, “light-detecting”, “light-sensing” and any other similar terms can be used interchangeably.

Spatial descriptions, such as “above”, “over,”, “under”, “top”, and “bottom” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the term “intrinsic” means that the semiconductor material is without intentionally adding dopants. The term “over” can indicate partially over or totally over.

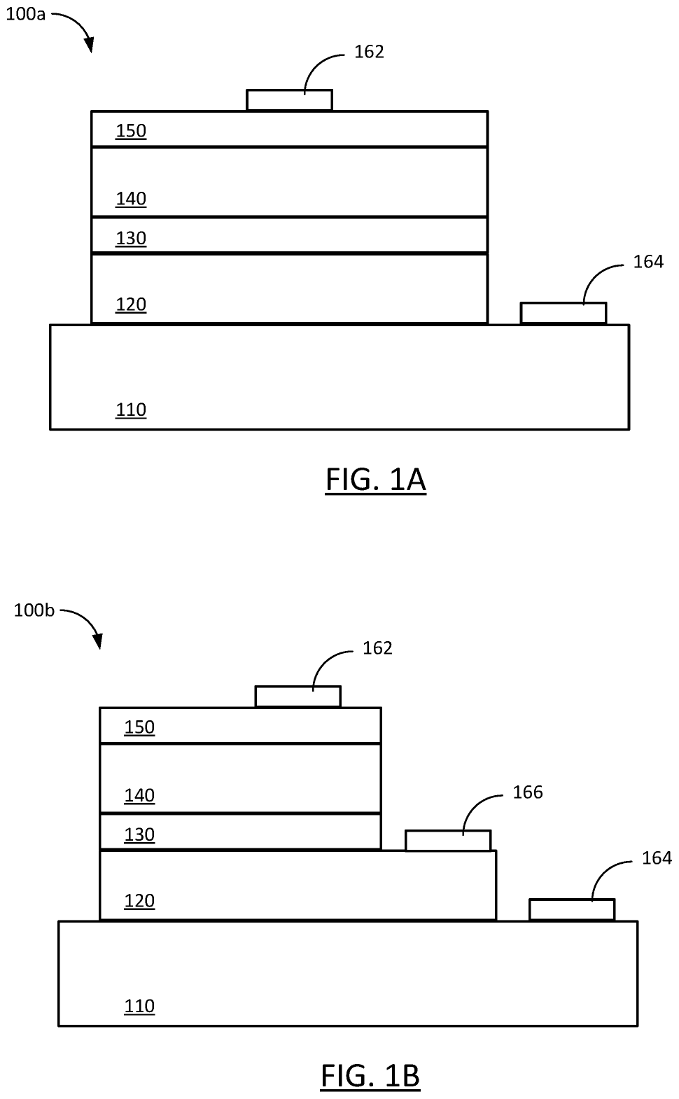

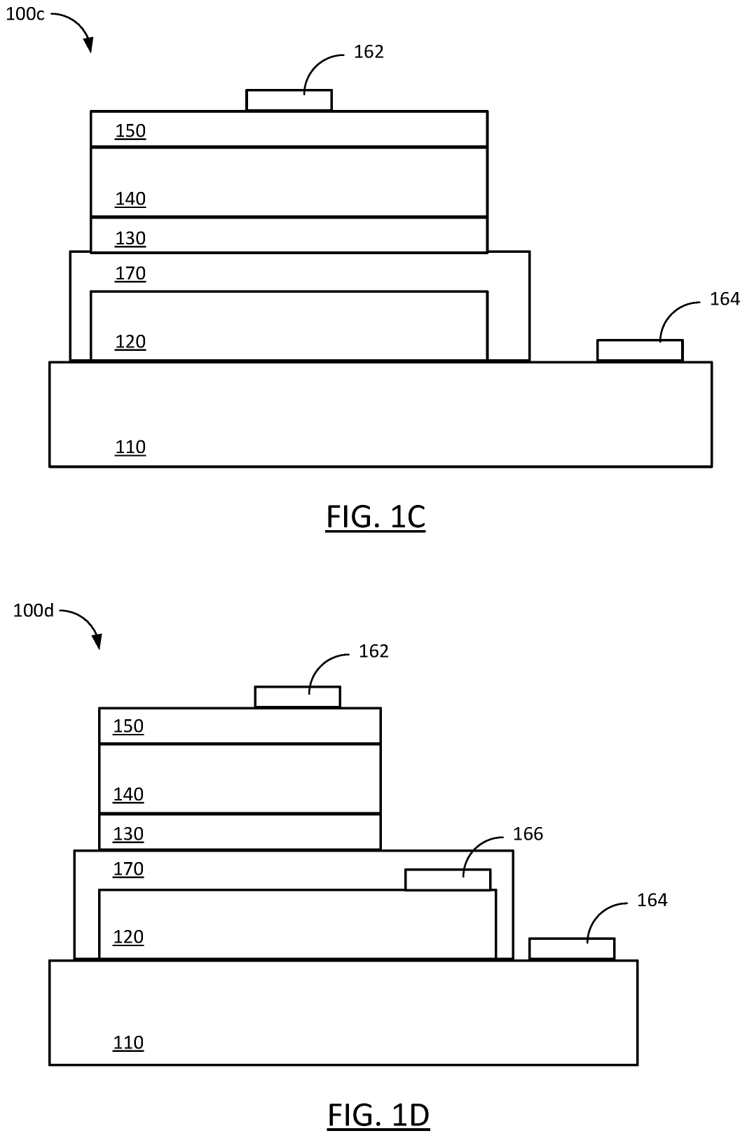

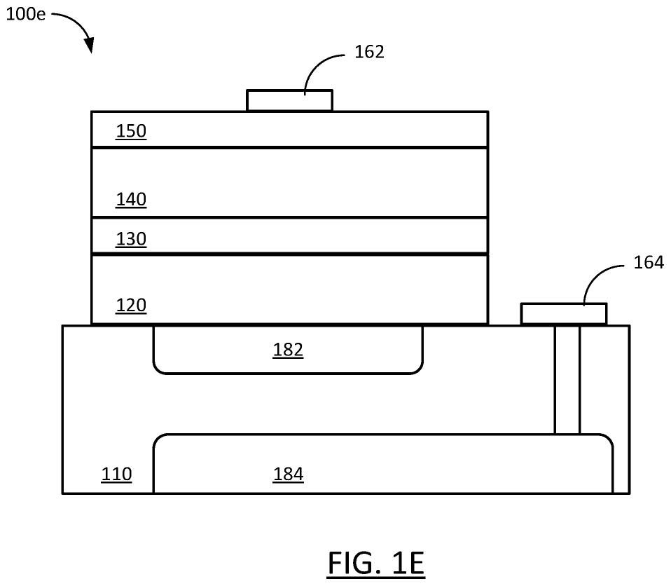

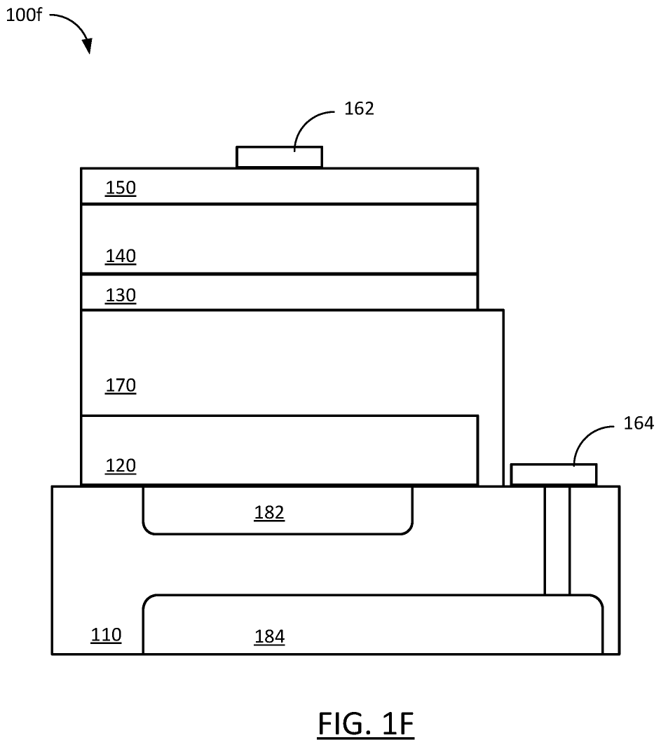

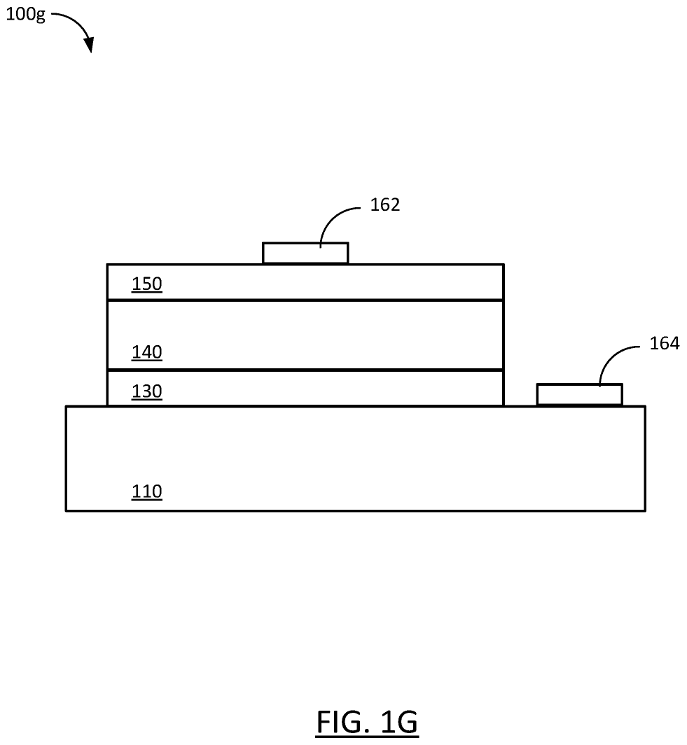

FIG. 1A shows a photodetector 100a. The photodetector 100a includes a first photo-detecting layer 110, a second photo-detecting layer 140, a first buffer layer 150, and a second buffer layer 130. The first photo-detecting layer 110 includes a first absorption region configured to absorb light in the visible spectrum and/or the NIR spectrum. As an example, the first photo-detecting layer 110 may be silicon.

The second photo-detecting layer 140 is formed over the first photo-detecting layer 110, where the second photo-detecting layer 140 includes a second absorption region configured to absorb light in at least the MIR spectrum. As an example, the second photo-detecting layer 140 may include black phosphorus, or any other two-dimensional material (e.g., Graphene, MXene (Graphene-like layer materials), TIs (Topological insulators), TMDc (Transition Metal Dichalcogenides), etc.). The first buffer layer 150 is formed over the second photo-detecting layer 140, and the second buffer layer 130 is formed over the first photo-detecting layer 110 and under the second photo-detecting layer 140. The first buffer layer 150 and the second buffer layer 130 are formed to prevent carrier relaxation and/or material oxidation. The first buffer layer 150 and the second buffer layer 130 also serve as conduction layers. As an example, the first buffer layer 150 and the second buffer layer 130 may be a mono-layer or multi-layer graphene. In some implementations, the thickness of the first buffer layer 150 and the second buffer layer 130 is on the order of a nanometer.

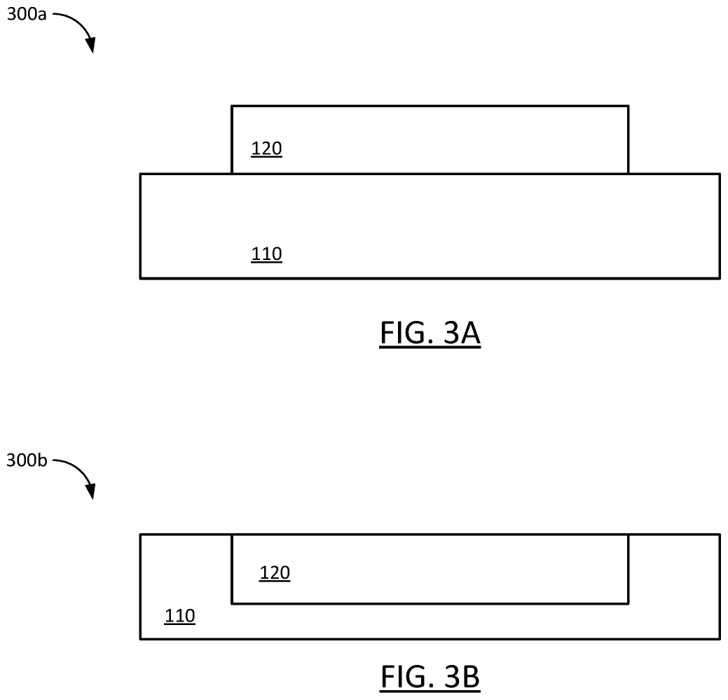

In some implementations, the photodetector 100a may further include a third photo-detecting layer 120. The third photo-detecting layer 120 may be formed between the first photo-detecting layer 110 and the second photo-detecting layer 140, where the third photo-detecting layer 120 includes a third absorption region configured to absorb light in at least the NIR and/or SWIR spectrum. As an example, the third photo-detecting layer 120 may be germanium, or GeₓSi₁₋ₓ, where 0≤x≤1. Using a germanium-on-silicon platform as an example, germanium-based materials (e.g., the third photo-detecting layer 120 formed using undoped/doped germanium, silicon-germanium compounds, etc.) may be deposited on a silicon-based substrate (e.g., the first photo-detecting layer 110) as a mesa (e.g., referring to the example structure 300a in FIG. 3A) or embedded in pattern-etched trenches (e.g., referring to the example structure 300b in FIG. 3B) in the silicon-based substrate using a CMOS-compatible fabrication process.

In some implementations, the photodetector 100a may further include a first contact 164 and a second contact 162. The first contact 164 may be formed over the first photo-detecting layer 110, and the second contact 162 may be formed over the first buffer layer 150. The first contact 164 and the second contact 162 may include metals or alloys, such as Al, Cu, W. Ti, Ta—TaN—Cu stack, or Ti—TiN—W stack. During operation, a voltage bias may be applied between the first contact 164 and the second contact 162 to extract photo-carriers (e.g., electrons) from the second photo-detecting layer 140 and/or the third photo-detecting layer 120 to the first photo-detecting layer 110, so the photo-carriers may be processed by a circuitry (e.g., readout circuit) electrically coupled to the first contact 164. In some implementations, the second photo-detecting layer 140 is formed over a first portion of the first photo-detecting layer 110, and the first contact 164 is formed over a second portion of the first photo-detecting layer 110.

Referring to FIG. 1B as another example photodetector 100b, in some implementations, the photodetector 100b may include a third contact 166. The third contact 166 is formed over the third photo-detecting layer 120. During operation, voltage biases may be applied on the first contact 164, the second contact 162, and the third contact 166 to extract one type of photo-carriers (e.g., electrons) to the first contact 164, and the other type of photo-carriers (e.g., holes) to the second contact 162 (e.g., holes generated by MIR light) and the third contact 166 (e.g., holes generated by NIR/SWIR light).

In some implementations, the first photo-detecting layer 110 (e.g., Si) may be p-doped, the third photo-detecting layer 120 (e.g., Ge) may be p-doped, and the second photo-detecting layer 140 (black phosphorus) may include n-doping, p-doping, or may be intrinsic. In some other implementations, the first photo-detecting layer 110 (e.g., Si) may be n-doped, the third photo-detecting layer 120 (e.g., Ge) may be p-doped, and the second photo-detecting layer 140 (black phosphorus) may be p-doped.

Referring to FIGS. 1C and 1D as another example photodetectors 100c or 100d, in some implementations, the photodetector 100c/100d may include a passivation layer 170 formed between the third photo-detecting layer 120 and the second buffer layer 130. The passivation layer 170 may be epitaxial silicon or amorphous silicon that is formed to improve an adhesion between the third photo-detecting layer 120 and the second buffer layer 130.

In some implementations, the first photo-detecting layer 110 (e.g., Si) may be p-doped, the third photo-detecting layer 120 (e.g., Ge) may be p-doped, the passivation layer 170 (e.g., epitaxial Si) may be p-doped, and the second photo-detecting layer 140 (black phosphorus) may include n-doping, p-doping, or may be intrinsic (or include an intrinsic region). In some other implementations, the first photo-detecting layer 110 (e.g., Si) may be n-doped, the third photo-detecting layer 120 (e.g., Ge) may be p-doped, the passivation layer 170 (e.g., epitaxial Si) may be p-doped, and the second photo-detecting layer 140 (e.g., black phosphorus) may be p-doped.

Referring to FIGS. 1E and 1F as another example photodetectors 100e or 100f, in some implementations, the photodetector 100e/100f may include a charge region 182 and a well region 184. The charge region 182 is configured to amplify photo-carriers generated from the second photo-detecting layer 140 and/or the third photo-detecting layer 120 when operated above the breakdown voltage, such that the photodetector 100e/100f can be operated as an avalanche photodiode (APD) or a single-photon avalanche diode (SPAD). The well region 184 is electrically coupled to the second contact 164, and is configured to guide the amplified photo-carriers to the second contact 164 for further processing.

Referring to FIG. 1G as another example photodetector 100g, in some implementations, the photodetector 100g includes a first photo-detecting layer 110, a second photo-detecting layer 140, a first buffer layer 150, and a second buffer layer 130. The first photo-detecting layer 110 includes a first absorption region configured to absorb light in the visible spectrum and/or the NIR spectrum. As an example, the first photo-detecting layer 110 may be silicon. The second photo-detecting layer 140 includes a second absorption region configured to absorb light in at least the mid-infrared (MIR) spectrum. As an example, the second photo-detecting layer 140 may include black phosphorus, or any other two-dimensional material (e.g., Graphene, MXene (Graphene-like layer materials), TIs (Topological insulators), TMDc (Transition Metal Dichalcogenides), etc.).

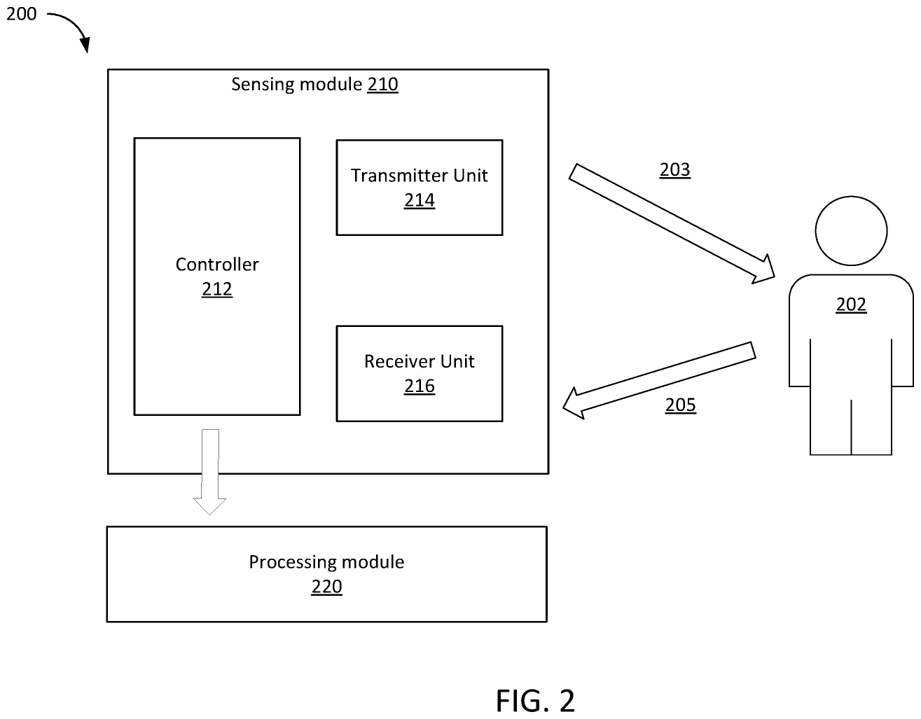

FIG. 2 is a block diagram of an example of a sensing system 200. The sensing system 200 may include a sensing module 210 and a processing module 220 configured process data associated with a detected object 202. The sensing system 200 or the sensing module 210 may be implemented on a mobile device (e.g., a smartphone, a tablet, vehicle, drone, etc.), an ancillary device (e.g., a wearable device) for a mobile device, a computing system on a vehicle or in a fixed facility (e.g., a factory), a robotics system, a surveillance system, or any other suitable device and/or system.

The sensing module 210 includes a transmitter unit 214, a receiver unit 216, and a controller 212. During operation, the transmitter unit 214 may emit an emitted light 203 toward a target object 202. The receiver unit 216 may receive reflected light 205 reflected from the target object 202. The controller 212 may drive at least the transmitter unit 214 and the receiver unit 216. In some implementations, the receiver unit 216 and the controller 212 are implemented on one semiconductor chip, such as a system-on-a-chip (SoC). In some cases, the transmitter unit 214 is implemented by two different semiconductor chips, such a laser emitter chip on III-V substrate and a Si laser driver chip on Si substrate.

The transmitter unit 214 may include one or more light sources, control circuitry controlling the one or more light sources, and/or optical structures for manipulating the light emitted from the one or more light sources. In some embodiments, the light source may include one or more light emitting diodes (LEDs) or vertical-cavity surface-emitting lasers (VCSELs) emitting light that can be absorbed by the absorption region in the optical sensing apparatus. For example, the one or more LEDs or VCSEL may emit light with a peak wavelength within the visible, NIR, SWIR, MIR, or any other applicable wavelengths. In some embodiments, the emitted light from the light sources may be collimated by the one or more optical structures. For example, the optical structures may include one or more collimating lens.

The receiver unit 216 may include one or more optical sensing apparatus, e.g., any one or more of photodetectors 100a-100f. The receiver unit 216 may further include a control circuitry for controlling the control circuitry and/or optical structures for manipulating the light reflected from the target object 202 toward the one or more optical sensing apparatus. In some implementations, the optical structures include one or more lens that receive a collimated light and focus the collimated light towards the one or more optical sensing apparatus.

The processing module 220 may be implemented to perform in applications such as proximity sensing, bio-signal detection, material recognition, facial recognition, eye-tracking, gesture recognition, 3-dimensional model scanning/video recording, motion tracking, autonomous vehicles, and/or augmented/virtual reality.

As used herein and not otherwise defined, the terms “substantially” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to +10% of that numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%.

While the concepts have been described by way of examples and in terms of embodiments, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An optical sensing apparatus comprising:
a first photo-detecting layer comprising a first absorption region configured to absorb light in at least a visible spectrum;
a second photo-detecting layer formed over the first photo-detecting layer, the second photo-detecting layer comprising a second absorption region configured to absorb light in at least a mid-infrared spectrum;
a first buffer layer formed over the second photo-detecting layer; and
a second buffer layer formed over the first photo-detecting layer and under the second photo-detecting layer.

2. The optical sensing apparatus of claim 1, further comprising:
a first contact formed over the first photo-detecting layer; and
a second contact formed over the first buffer layer.

3. The optical sensing apparatus of claim 2, wherein the first photo-detecting layer further comprises a charge region configured to amplify charge-carriers generated in the second absorption region.

4. The optical sensing apparatus of claim 3, wherein the first photo-detecting layer further comprises a well region electrically coupled to the second contact, the well region configured to guide the amplified charge-carriers to the second contact.

5. The optical sensing apparatus of claim 1, further comprising:
a third photo-detecting layer formed between the first photo-detecting layer and the second photo-detecting layer, the third photo-detecting layer comprising a third absorption region configured to absorb light in at least a short-wavelength mid-infrared spectrum.

6. The optical sensing apparatus of claim 5, further comprising:
a third contact formed over the third photo-detecting layer.

7. The optical sensing apparatus of claim 5, further comprising:
a passivation layer formed between the third photo-detecting layer and the second buffer layer.

8. The optical sensing apparatus of claim 7, wherein the first photo-detecting layer comprises silicon, the second photo-detecting layer comprises a two-dimensional material, the third photo-detecting layer comprises germanium, and the passivation layer comprises epitaxy silicon or amorphous silicon.

9. The optical sensing apparatus of claim 7, wherein the first photo-detecting layer includes p-doping, the second photo-detecting layer includes p-doping, n-doping, or an intrinsic region, the third photo-detecting layer includes p-doping, and the passivation layer includes p-doping.

10. The optical sensing apparatus of claim 7, wherein the first photo-detecting layer includes n-doping, the second photo-detecting layer includes p-doping, the third photo-detecting layer includes p-doping, and the passivation layer including p-doping.

11. The optical sensing apparatus of claim 1, wherein at least one of the first buffer layer or the second buffer layer comprises a monolayer graphene or a multi-layer graphene.

12. An optical sensing apparatus comprising:
a silicon layer comprising a first absorption region configured to absorb light in at least a visible spectrum;
a germanium layer formed over the silicon layer, the germanium layer comprising a second absorption region configured to absorb light in at least a short-wave infrared (SWIR) spectrum;
a black phosphorus layer formed over the germanium layer, the black phosphorus layer comprising a third absorption region configured to absorb light in at least a mid-infrared spectrum;
a first buffer layer formed over the black phosphorus layer; and
a second buffer layer formed over the silicon layer and under the black phosphorus layer.

13. The optical sensing apparatus of claim 12, further comprising a silicon-based passivation layer formed between the germanium layer and the second buffer layer.

14. The optical sensing apparatus of claim 12, wherein the silicon layer further comprises a charge region configured to amplify charge-carriers generated in the black phosphorus layer.

15. The optical sensing apparatus of claim 14, wherein the silicon layer further comprises a well region configured to guide the amplified charge-carriers to a readout circuitry.

16. The optical sensing apparatus of claim 12, wherein at least one of the first buffer layer or the second buffer layer comprises a monolayer graphene or a multilayer graphene.

17. An optical sensing apparatus comprising:
a silicon layer comprising a first absorption region configured to absorb light in at least a visible spectrum;
a germanium layer formed over the silicon layer, the germanium layer comprising a second absorption region configured to absorb light in at least a SWIR spectrum;
a two-dimensional-material layer formed over the germanium layer, the two-dimensional-material layer comprising a third absorption region configured to absorb light in at least a mid-infrared spectrum;
a first buffer layer formed over the two-dimensional-material layer;
a second buffer layer formed over the silicon layer and under the two-dimensional-material layer.

18. The optical sensing apparatus of claim 17, wherein the two-dimensional-material layer comprises graphene, MXene, topological insulators, or transition metal dichalcogenides.

19. The optical sensing apparatus of claim 17, wherein the silicon layer further comprises a charge region configured to amplify charge-carriers generated in the two-dimensional-material layer.

20. The optical sensing apparatus of claim 17, further comprising a silicon-based passivation layer formed between the germanium layer and the second buffer layer.
